(19) United States
(12) Patent Application Publication
(10) Pub. No.: US 2014/0136931 A1
(43) Pub. Date: May 15, 2014

(54) ERROR-CORRECTING DECODER

(71) Applicants: Takahiko Nakamura, Tokyo (JP); Wataru Matsumoto, Tokyo (JP)

(72) Inventors: Takahiko Nakamura, Tokyo (JP); Wataru Matsumoto, Tokyo (JP)

(73) Assignee: MITSUBISHI ELECTRIC CORPORATION, Tokyo (JP)

(21) Appl. No.: 14/129,220

(22) PCT Filed: Jun. 26, 2012
(86) PCT No.: PCT/JP12/66231

§ 371 Date: Dec. 24, 2013

(30) Foreign Application Priority Data
Aug. 24, 2011 (JP) 2011-182585

(51) Int. Cl. H03M 13/05

(52) U.S. Cl. CPC H03M 13/05
USPC 714/785

(57) ABSTRACT

Provided is an error-correcting decoder including: a syndrome generation unit for calculating, as a syndrome, coefficients of a residual polynomial that are obtained by dividing received data by a generator polynomial; information bit error pattern generation unit for generating all error patterns of information bits; a check bit error pattern generation unit for calculating, for each of the error patterns of the information bits, an error pattern of check bits based on the syndrome value; and an error correction unit for correcting the error pattern generated for a combination of codes having a weight of the error patterns of the information bits and the check bits smaller than a threshold value.

### TECHNICAL FIELD

The present invention relates to an error-correcting decoder for correcting and decoding an error in a code of received data in digital data transmission.

### BACKGROUND ART

In a conventional error-correcting decoder, in order to perform correction for the case where a correction bit count exceeds an error-correctable bit count, which is determined by a minimum distance of a code, an error pattern that is uniquely identifiable for a syndrome calculated based on a received sequence is stored in advance in a read-only memory (ROM), to thereby obtain an error vector to perform error correction (for example, Patent Literature 1).

Further, in another method of performing correction for the case where a correction bit count exceeds an error-correctable bit count, which is determined by a minimum distance of a code, a result of hard decision decoding performed based on the syndrome calculated by using the received sequence and a result of soft decision decoding performed by using likelihood information are used so as to perform the error correction for the case where the correction bit count exceeds the error-correctable bit count, which is determined by the minimum distance of the code (for example, Patent Literature 2).

### CITATION LIST

### Patent Literature

[PTL 1] JP 04-88725 A

[PTL 2] JP 10-256919 A

### SUMMARY OF INVENTION

### Technical Problems

In a conventional error-correcting decoder such as the one disclosed in Patent Literature 1, the following problem arises. Specifically, the ROM is required in order to output the error pattern for the syndrome, and in a case where a code having a large check bit count of an error-correcting code is used for the purpose of enhancing an error correction capability, the bit width of the syndrome is increased and thus the capacity of the ROM is increased.

The present invention has been made to solve the above-mentioned problem, and enables, in a case where a check bit length is long, correction to be performed for the case where the correction bit count exceeds the error-correctable bit count, which is determined by the minimum distance of the code without using a memory.

Moreover, in a conventional error-correcting decoder such as the one disclosed in Patent Literature 2, there is a problem in that a circuit scale is increased because a soft decision generator circuit for generating soft decision information based on a reception state and a soft decision decoder are required.

The present invention has been made to solve the above-mentioned problem, and enables correction to be performed for the case where a correction bit count exceeds an error-correctable bit count, which is determined by a minimum distance of a code while reducing the circuit scale by performing decoding with use of only hard decision information.

### Solution to Problems

An error-correcting decoder according to one embodiment of the present invention includes: a syndrome generation unit for calculating, as a syndrome, coefficients of a residual polynomial that are obtained by dividing received data by a generator polynomial; information bit error pattern generation unit for generating all error patterns of information bits; a check bit error pattern generation unit for generating a syndrome assuming that every check bit portion is 0 and an information bit portion is a received sequence of each of the error patterns of the information bits from the information bit error pattern generation unit and for calculating an error pattern of check bits based on the generated syndrome and the syndrome sent from the syndrome generation unit; and an error correction unit for correcting an error pattern generated for a combination of codes having a weight of the error patterns of the information bits and the check bits smaller than a predetermined value.

### Advantageous Effects of Invention

According to the error-correcting decoder of the present invention, the error patterns of the check bit portion are generated for all the error patterns of the information bit portion based on the generated syndrome value, and the error correction is performed when the entire error bit count is smaller than the predetermined threshold value. Accordingly, the following effects can be attained. Specifically, by setting the threshold value to the bit count larger than the error bit count determined by the minimum distance of the code, the error patterns can be generated even when the decoder does not include the ROM that outputs the error patterns directly from the syndrome. Moreover, the error correction capability can be enhanced by setting the threshold value to the value larger than the error-correctable bit count determined by the minimum distance of the code.

### BRIEF DESCRIPTION OF DRAWINGS

FIG. 1 is a block diagram of an error-correcting decoder according to a first embodiment of the present invention.

FIG. 2 is a block diagram of an error-correcting decoder according to a second embodiment of the present invention.

FIG. 3 is a block diagram of an error-correcting decoder according to a third embodiment of the present invention.

FIG. 4 is a block diagram of a secret key generator for generating secret key information by applying the error-correcting decoder of the present invention.

FIG. 5 is a block diagram of another secret key generator for generating the secret key information by applying the error-correcting decoder of the present invention.

### DESCRIPTION OF EMBODIMENTS

### First Embodiment

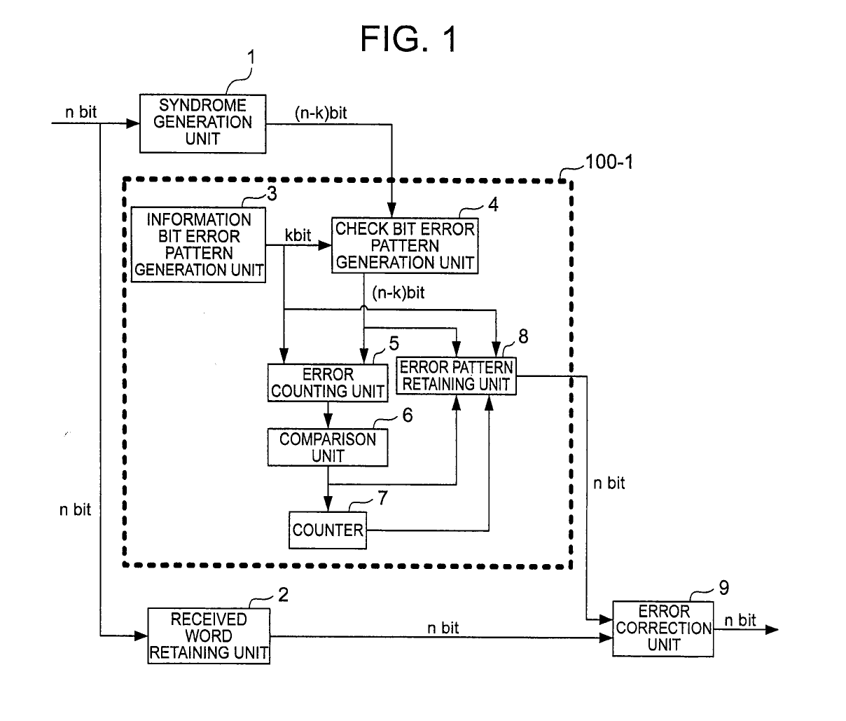

FIG. 1 is a block diagram illustrating an error-correcting decoder according to a first embodiment of the present invention. In FIG. 1, the error-correcting decoder includes a syndrome generation unit 1 for generating a syndrome for an input of an n-bit received word, a received word retaining unit 2 for retaining n-bit received data, an information bit error pattern generation unit 3 for generating 2^{k} types of all error patterns with regard to error patterns of k information bits, a check bit error pattern generation unit 4 for generating error patterns of an (n−k)-bit check bit portion by using the information bit error patterns generated by the information bit error pattern generation unit 3 and the syndrome generated by the syndrome generation unit 1, and an error counting unit 5 for counting an error bit count of the entire received word based on the information bit error patterns generated by the information bit error pattern generation unit 3 and the error patterns of the check bit portion generated by the check bit error pattern generation unit 4.

The error-correcting decoder further includes a comparison unit 6 for comparing an error bit count output from the error counting unit 5 with a predetermined error correction threshold value, a counter 7 for counting the number of combinations of error patterns whose error bit count is determined by the comparison unit 6 as being smaller than the threshold value, an error pattern retaining unit 8 for storing the error pattern that is generated when the value of the counter 7 is 0 and whose error bit count is determined by the comparison unit 6 as being smaller than the threshold value, and an error correction unit 9 for performing error correction by adding the error pattern retained in the error pattern retaining unit 8 to the received word retained in the received word retaining unit 2. The error-correcting decoder still further includes an error vector calculation unit 100-1 according to the first embodiment, which is surrounded by the broken line. The error vector calculation unit 100-1 includes the above-mentioned information bit error pattern generation unit 3, check bit error pattern generation unit 4, error counting unit 5, comparison unit 6, counter 7, and error pattern retaining unit 8.

A description is now given of an operation. In an (n,k) cyclic code, an n-bit received word is input, and the syndrome generation unit 1 calculates an (n−k)-bit syndrome. The syndrome is calculated as follows. When the n-bit received sequence is expressed by a polynomial r(x) (r(x) is a polynomial of degree (n−1)), coefficients of a residual polynomial obtained by dividing the polynomial r(x) by a generator polynomial g(x) (g(x) is a polynomial of degree (n−k)) are calculated by a linear feedback shift register, and the coefficients are used as the syndrome. In addition, the n-bit received word sequence is stored in the received word retaining unit 2.

Next, the information bit error pattern generation unit 3 generates the 2^{k} types of all error patterns of the k information bits.

First, while assuming that the check bits are all 0, the check bit error pattern generation unit 4 receives the error patterns for the respective information bits from the information bit error pattern generation unit 3 as the received sequence to generate the syndrome. The syndrome can be calculated by a combinational logic circuit for the information bit error patterns. The syndrome generated based on the error pattern of the information bits is then added to the syndrome calculated by the syndrome generation unit 1 to generate the error patterns of the check bits.

Next, the error counting unit 5 calculates (counts) the number of bits whose value is 1, that is, an error bit count e of the error pattern of the information bits generated by the information bit error pattern generation unit 3 and the error pattern of the check bits generated by the check bit error pattern generation unit 4. The comparison unit 6 compares the error bit count e counted by the error counting unit 5 with a predetermined correction bit threshold value u, and counts up the counter 7 when the value of the error bit count e is the correction bit threshold value u or smaller. Further, when the value of the error bit count e is the correction bit threshold value u or smaller and the counter 7 has a value of 0 before being incremented, the error pattern is retained in the error pattern retaining unit 8. When the value of the error bit count e is the correction bit threshold value u or smaller and the counter 7 has a value other than 0 before being incremented, the value of an error retained in the error pattern retaining unit 8 is cleared.

After the above-mentioned processing is performed on the error patterns of all information bit sequences, the error correction unit 9 adds the error pattern stored in the error pattern retaining unit 8 to the received word sequence retained in the received word retaining unit 2, and outputs the decoding result.

In the embodiment described above, the error correction is performed only when there is one combination whose value of the error bit count e is the correction bit threshold value u or smaller, but the error pattern that is detected first when there are two or more combinations may be decoded.

In the embodiment described above, the error patterns of the check bit portion are generated based on the generated syndrome value for all error patterns of the information bit portion, and the error correction is performed when the entire error bit count is smaller than the predetermined threshold value. Accordingly, the following effects can be attained. Specifically, by setting the threshold value to a bit count larger than the error bit count determined by a minimum distance of a code, the error patterns can be generated even when the decoder does not include the ROM that outputs the error patterns directly from the syndrome. Moreover, an error correction capability can be enhanced by setting the threshold value to a value larger than an error-correctable bit count determined by the minimum distance of the code.

### Second Embodiment

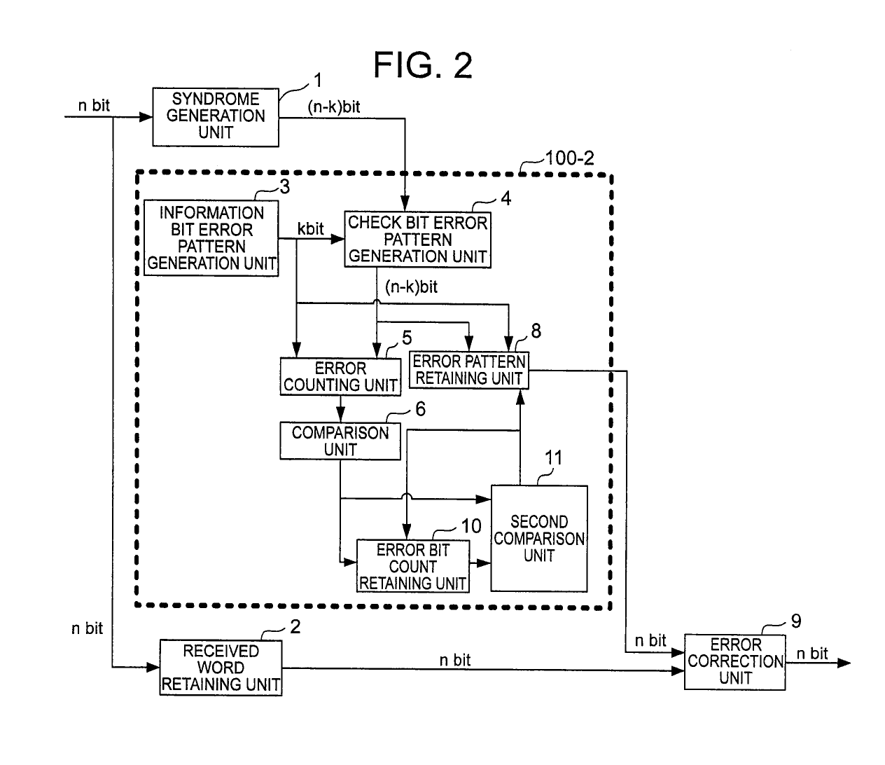

FIG. 2 is a block diagram illustrating an error-correcting decoder according to a second embodiment of the present invention. In FIG. 2, the error-correcting decoder includes an error bit count retaining unit 10 for retaining a minimum value of the error bit count in a series of operation of the error correction operation for one received word and a second comparison unit 11 for comparing the error bit count output from the comparison unit 6 with the value stored in the error bit count retaining unit 10. The other reference numerals represent the same components as those of the first embodiment. The error-correcting decoder further includes an error vector calculation unit 100-2 according to the second embodiment, which is surrounded by the broken line. The error vector calculation unit 100-2 includes the information bit error pattern generation unit 3, the check bit error pattern generation unit 4, the error counting unit 5, the comparison unit 6, the error pattern retaining unit 8, the error bit count retaining unit 10, and the second comparison unit 11.

A description is now given of an operation. The syndrome generation unit 1 generates the syndrome based on the received word. The check bit error pattern generation unit 4 then generates the error patterns of the check bits based on the error patterns of the information bits generated by the information bit error pattern generation unit 3 and the syndrome sent from the syndrome generation unit 1. The error counting unit 5 calculates (counts) the number of bits whose value is 1, that is, the error bit count e of the error pattern of the information bits and the error pattern of the check bits. The comparison unit 6 compares the error bit count e counted by the error counting unit 5 with the predetermined correction bit threshold value u. The above-mentioned operation is the same as that of the first embodiment.

When the comparison unit 6 determines that the value of the error bit count e is the correction bit threshold value u or smaller, the second comparison unit 11 compares the error bit count e with a minimum error bit count emin retained in the error bit count retaining unit 10. At first, the minimum error bit count emin has a code length n. When the error bit count e is smaller than the minimum error bit count emin, the value of the error bit count e is retained in the error bit count retaining unit 10, and the error patterns generated by the information bit error pattern generation unit 3 and the check bit error pattern generation unit 4 are retained in the error pattern retaining unit 8.

When the value of the error bit count e is equal to the minimum error bit count emin, the value of the error pattern retaining unit 8 is cleared. When the value of the error bit count e is larger than the minimum error bit count emin, the values of the error pattern retaining unit 8 and the error bit count retaining unit 10 remain as they are and are not updated.

After the above-mentioned processing is performed on the error patterns of all information bit sequences, the error correction unit 9 adds the error pattern stored in the error pattern retaining unit 8 to the received word sequence retained in the received word retaining unit 2, and outputs the decoding result.

In the embodiment described above, the correction is not performed when there are two error patterns having the same value of the minimum error bit count emin, but one of those error patterns may be selected to perform decoding.

In the embodiment described above, the error patterns of the check bit portion are generated based on the generated syndrome value for all error patterns of the information bit portion, and the error correction is performed when there is only one code having the smallest error bit count among the error patterns having the entire error bit count smaller than the predetermined threshold value. Accordingly, decoding may be performed even when there are a plurality of candidates for the decoding result in the first embodiment, and hence such an effect that the error correction capability can be enhanced is attained.

### Third Embodiment

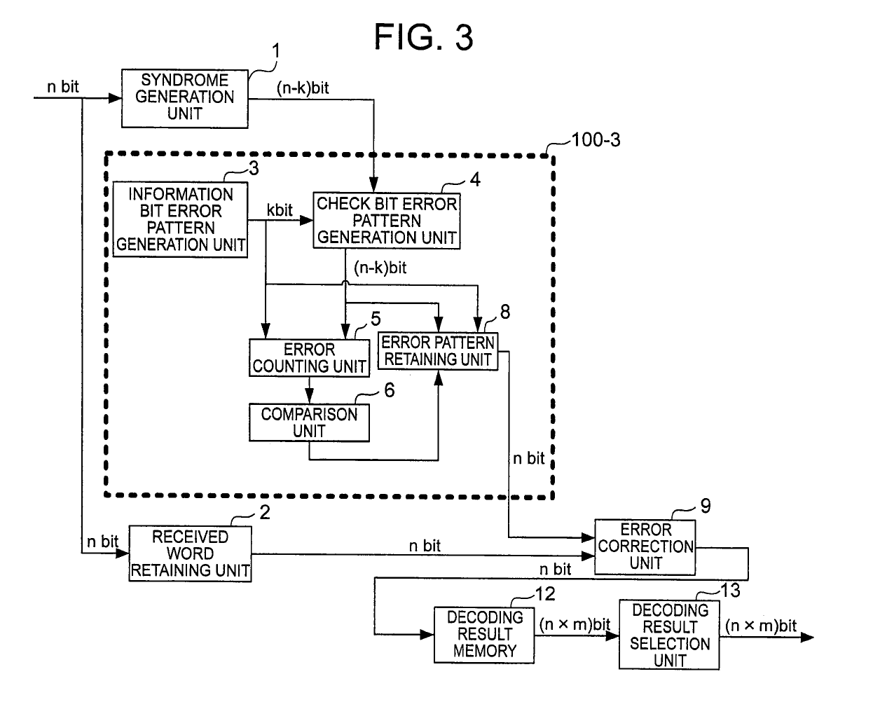

FIG. 3 is a block diagram illustrating an error-correcting decoder according to a third embodiment of the present invention. In FIG. 3, the error-correcting decoder includes a decoding result memory 12 for storing a plurality of decoding results corresponding to m codes that have been subjected in advance to the error correction and decoding performed by the error correction unit 9 on m blocks enabling the error detection and a decoding result selection unit 13 for verifying, for every combination, whether or not there is an error in the decoding results corresponding to the m codes stored in the decoding result memory 12 to select a combination having no error. The other reference numerals represent the same components as those of the first embodiment.

The error-correcting decoder further includes an error vector calculation unit 100-3 according to the third embodiment, which is surrounded by the broken line. The error vector calculation unit 100-3 includes the information bit error pattern generation unit 3, the check bit error pattern generation unit 4, the error counting unit 5, the comparison unit 6, and the error pattern retaining unit 8.

A description is now given of an operation. The syndrome generation unit 1 generates the syndrome based on the received word. The check bit error pattern generation unit 4 then generates the error patterns of the check bits based on the error patterns of the information bits generated by the information bit error pattern generation unit 3 and the syndrome sent from the syndrome generation unit 1. The error counting unit 5 calculates (counts) the number of bits whose value is 1, that is, the error bit count e of the error pattern of the information bits and the error pattern of the check bits. The comparison unit 6 compares the error bit count e counted by the error counting unit 5 with the predetermined correction bit threshold value u. The above-mentioned operation is the same as that of the first embodiment or that of the second embodiment. When a comparison result obtained by the comparison unit 6 indicates that the value of the error bit count e is the correction bit threshold value u or smaller, the error pattern of the information bits and the error pattern of the check bits are retained in the error pattern retaining unit 8.

After the above-mentioned processing is performed on the error patterns of all information bit sequences, the error correction unit 9 adds the error pattern stored in the error pattern retaining unit 8 to all the received word sequences retained in the received word retaining unit 2, and outputs one or a plurality of decoding results to be stored in the decoding result memory 12.

The above-mentioned operation is performed on the m blocks enabling the error detection in advance, and all the decoding results for the m codes are retained in the decoding result memory 12. The decoding result selection unit 13 selects, for each code, one decoding result for the decoding results for the m codes stored in the decoding result memory 12, performs error detection, and outputs the combination having no error detected as a final decoding result.

In the embodiment described above, although the error detection is performed when a plurality of candidates are output as a result of performing the error correction in the first embodiment and the second embodiment, the plurality of obtained decoding results are output and the combination having no error detected is selected and output from among the plurality of decoding results. Accordingly, the result that is not corrected in the first embodiment or the second embodiment can be corrected, and hence such an effect that the error correction capability is further enhanced is attained.

### Fourth Embodiment

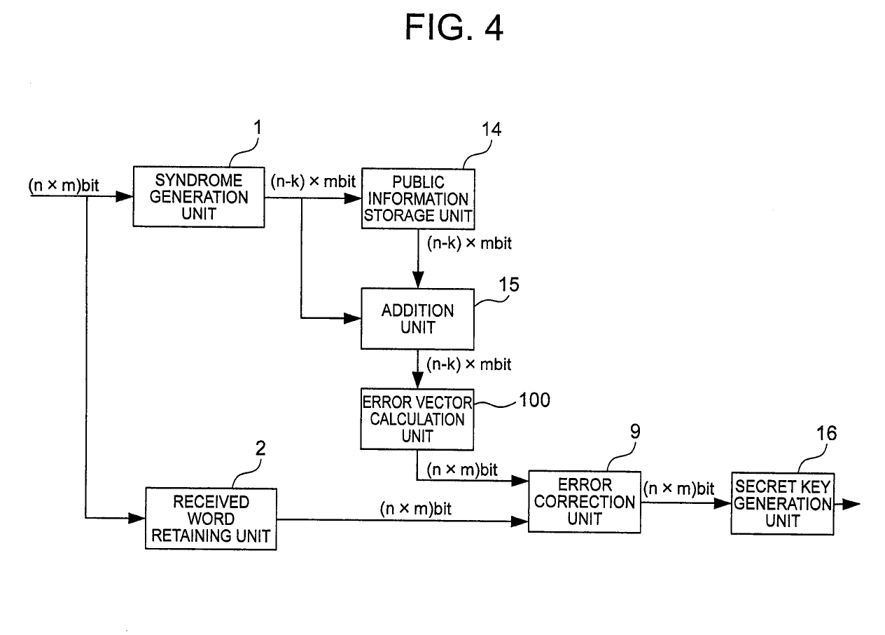

FIG. 4 is a block diagram illustrating, as an application example of the error-correcting decoder of the present invention, a secret key generator for generating secret key information based on device-specific information such as circuit delay characteristics and a signal shape caused by a glitch. The device-specific information is susceptible to error due to a temperature change, a voltage fluctuation, and other such factors.

In FIG. 4, the secret key generator includes a public information storage unit 14 for storing, as public information, the syndrome generated based on the device-specific information read out first, an addition unit 15 for adding the public information stored in the public information storage unit 14 to the syndromes generated based on pieces of device-specific information read out for the second and subsequent times, and an error vector calculation unit 100, which corresponds to one of the error vector calculation unit 100-1 according to the first embodiment to the error vector calculation unit 100-3 according to the third embodiment. The secret key generator further includes a secret key generation unit 16 for generating a secret key based on the decoding results for m code words output from the error correction unit 9. The other reference numerals correspond to the same reference numerals as those of the first embodiment.

A description is now given of an operation. First, (n×m)-bit device-specific information is read out, and the device-specific information is divided for every n bit. The syndrome generation unit 1 then calculates the syndrome for each piece of information, and stores the result of calculation in the public information storage unit 14 as the public information. After the public information is stored in the public information storage unit 14, the (n×m)-bit device-specific information is read out again in order to generate the secret key, and the syndrome generation unit 1 calculates the syndrome. Further, the device-specific data read out is stored in the received word retaining unit 2.

Next, the addition unit 15 adds the syndrome information that is generated first and stored in the public information storage unit 14 to the syndrome generated by the syndrome generation unit 1 based on the device-specific information read out secondly. Then, with the use of the value that is obtained by addition performed by the addition unit 15 as the syndrome, the error vector calculation unit 100 generates m sets of n-bit error vectors. Note that, the error vector calculation unit 100 corresponds to one of the error vector calculation units 100-1, 100-2, and 100-3 described above in the first, second, and third embodiments, respectively. The error correction unit 9 adds the error vector information generated by the error vector calculation unit 100 to the data retained in the received word retaining unit 2 to correct and decode the data, and the secret key generation unit 16 generates device-specific secret key information.

In the embodiment described above, based on the device-specific information that is susceptible to frequent error when read out, secret key information specific to the device can be generated, and the error correction capability is thus enhanced. It is therefore possible to reduce a period of time required for generating the secret key information.

### Fifth Embodiment

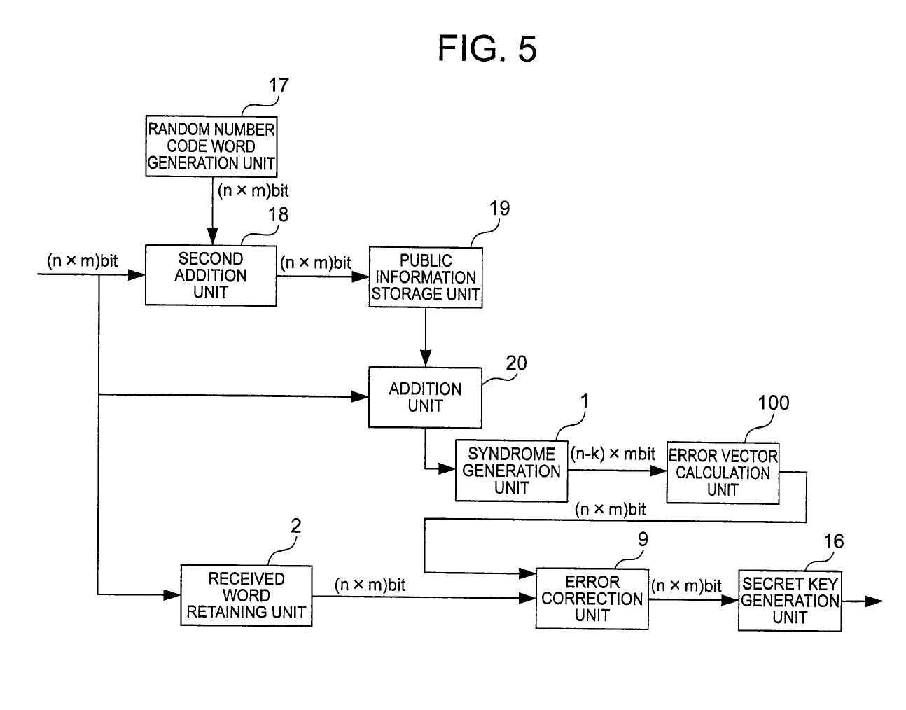

FIG. 5 is a block diagram illustrating a secret key generator for generating the secret key information based on the device-specific information according to another embodiment than the fourth embodiment illustrated in FIG. 4. As in the fourth embodiment, the device-specific information is also susceptible to error due to a temperature change, a voltage fluctuation, and other such factors.

In FIG. 5, the secret key generator includes a random number code word generation unit 17 for generating code word information based on a random number, a second addition unit 18 for adding the code word information generated by the random number code word generation unit 17 to the device-specific information read out first, a public information storage unit 19 for storing a result of addition performed by the second addition unit 18 as the public information, and an addition unit 20 for adding the public information to the pieces of device-specific information generated for the second and subsequent times. The other reference numerals represent the same components as those of the fourth embodiment.

A description is now given of an operation. First, the (n×m)-bit device-specific information is read out. The random number code word generation unit 17 next randomly generates the code words for m codes, and the second addition unit 18 adds the code words to the device-specific information read out. The result of addition is then stored in the public information storage unit 19. After the public information is stored in the public information storage unit 19, the (n×m)-bit device-specific information is read out again in order to generate the secret key, and the addition unit 20 adds the information to the public information. A result of the addition is input to the syndrome generation unit 1, which then calculates the syndromes. Moreover, the device-specific information read out is stored in the received word retaining unit 2. The error vector calculation unit 100 next generates m sets of n-bit error vectors for the syndromes generated by the syndrome generation unit 1. The error correction unit 9 adds the error vector information generated by the error vector calculation unit 100 to the data retained in the received word retaining unit 2 to correct and decode the data, and the secret key generation unit 16 generates device-specific secret key information.

Also in the embodiment described above, based on the device-specific information that is susceptible to frequent error when read out, secret key information specific to the device can be generated, and the error correction capability is thus enhanced. It is therefore possible to reduce a period of time required for generating the secret key information.

### INDUSTRIAL APPLICABILITY

The present invention is applicable to a device for correcting and decoding an error in a code of received data on a reception side of digital data transmission and to an error correction device for generating device-specific secret key information.

1. An error-correcting decoder, comprising:
a syndrome generation unit for calculating, as a syndrome, coefficients of a residual polynomial that are obtained by dividing received data by a generator polynomial;
information bit error pattern generation unit for generating all error patterns of information bits;
a check bit error pattern generation unit for generating a syndrome by receiving each of the error patterns of the information bits from the information bit error pattern generation unit as a received sequence and for calculating an error pattern of check bits based on the generated syndrome and the syndrome sent from the syndrome generation unit; and
an error correction unit for correcting the error pattern generated for a combination of codes having a weight of the error patterns of the information bits and the check bits smaller than a predetermined value.

2. An error-correcting decoder, comprising:
a syndrome generation unit for calculating, as a syndrome, coefficients of a residual polynomial that are obtained by dividing received data by a generator polynomial;
information bit error pattern generation unit for generating all error patterns of information bits;
a check bit error pattern generation unit for generating, assuming that a check bit portion is 0, a syndrome by receiving each of the error patterns of the information bits from the information bit error pattern generation unit as a received sequence and for calculating an error pattern of check bits based on the generated syndrome and the syndrome sent from the syndrome generation unit; and
an error correction unit for generating an error pattern for a combination of codes having a weight of the error patterns of the information bits and the check bits smaller than a predetermined value, and when there are a plurality of the error patterns, selecting the error pattern having a smallest error-correctable bit count to correct the selected error pattern.

3. An error-correcting decoder, comprising:
a syndrome generation unit for calculating, as a syndrome, coefficients of a residual polynomial that are obtained by dividing received data by a generator polynomial;
information bit error pattern generation unit for generating all error patterns of information bits;
a check bit error pattern generation unit for generating, assuming that a check bit portion is 0, a syndrome by receiving each of the error patterns of the information bits from the information bit error pattern generation unit as a received sequence and for calculating an error pattern of check bits based on the generated syndrome and the syndrome sent from the syndrome generation unit;
an error correction unit for generating an error pattern for a combination of codes having a weight of the error patterns of the information bits and the check bits smaller than a predetermined value, and correcting all the error patterns;
a decoding result memory for retaining all results of the correction performed by the error correction unit; and
a decoding result selection unit for performing error detection processing on the decoding results for a plurality of received words and outputting, as a final decoding result, a combination of the decoding results having no error detected.
